(19) United States
(12) Patent Application Publication
(10) Pub. No.: US 2008/0111588 A1
(43) Pub. Date: May 15, 2008

(54) Input buffer circuit

(75) Inventor: Mi Hye Kim, Gyeonggi-do (KR)

Correspondence Address: VENABLE LLP, P.O. BOX 34385, WASHINGTON, DC, 20043-9998, US

(73) Assignee: Hynix Semiconductor Inc., Gyeonggi-do (KR)

(21) Appl. No.: 11/822,815

(22) Filed: Jul. 10, 2007

(30) Foreign Application Priority Data
Nov. 13, 2006 (KR) 10-2006-0111851

(51) Int. Cl. H03K 19/00

(52) U.S. Cl. 327/108

(57) ABSTRACT

The input buffer circuit includes: a first buffer adapted to buffer a clock enable signal in modes other than a self refresh mode; a second buffer adapted to buffer the clock enable signal in the self refresh mode; and an output unit adapted to select output signals of the first and second buffers. In the input buffer circuit, the first buffer operates at a higher speed than the second buffer, and the amount of current consumed by the second buffer is smaller than the amount of current consumed by the first buffer.

### CROSS-REFERENCE TO RELATED PATENT APPLICATION

This application claims the benefit of Korean Patent Application No. 10-2006-0111851, filed on Nov. 13, 2006, in the Korean Intellectual Property Office, the disclosure of which is incorporated herein in its entirety by reference.

### BACKGROUND OF THE INVENTION

1. Technical Field

The present invention relates to an input buffer circuit, and more particularly, to an input buffer circuit for buffering a clock enable signal.

2. Related Art

The Joint Electron Device Engineering Council (JEDEC) prescribes the entry and exit for a self refresh mode of semiconductor memory devices such as DRAMs. Conventional semiconductor memory devices use one type of input buffer for buffering the clock enable signal regardless of the device's mode of operation. Thus, a conventional buffer may be adapted to operate at a high speed using a large amount of current, or operate at a low speed using a smaller amount of current, regardless of the operation mode.

In semiconductor memory devices such as DRAMs, it is generally more important to reduce current than to increase the operating speed in the self refresh mode. In contrast, in modes other than the self refresh mode, it is more important to increase the operating speed than to reduce the amount of current. In conventional memory devices having only one type of buffer, where the both the operating speed and the amount of current consumed as either high or low regardless of the operating mode, the conditions related to the amount of current consumed and the operating speed are not met. What is needed is a circuitry in memory devices capable of reducing the amount of current consumed by the device during the entry to self refresh mode.

### SUMMARY OF THE INVENTION

An embodiment of the present invention provides an input buffer circuit capable of meeting the conditions in respect to the amount of current consumed and an operating speed.

According to an embodiment of the present invention, an input buffer circuit includes: a first buffer that buffers an input signal when a control signal is activated; and a second buffer that buffers the input signal when the control signal is activated. In the input buffer circuit, the first and second buffers selectively operate to output a signal in response to the control signal.

According to another embodiment of the present invention, an input buffer circuit includes: a first buffer that buffers a clock enable signal in mode other than a self refresh mode; a second buffer that buffers the clock enable signal in the self refresh mode; and an output unit that selects output signals of the first and second buffers. In the input buffer circuit, the first buffer operates at a higher speed than the second buffer.

According to still another embodiment of the present invention, an input buffer circuit includes: a first buffer that buffers a clock enable signal in modes other than a self refresh mode; a second buffer that buffers the clock enable signal in a self refresh mode; and an output unit that selects output signals of the first and second buffers. In the input buffer circuit, the first buffer operates at a higher speed than the second buffer, and the amount of current consumed by the second buffer is smaller than the amount of current consumed by the first buffer.

The first buffer may be a differential buffer, and the second buffer may be a static buffer.

### BRIEF DESCRIPTION OF THE DRAWINGS

Various exemplary features and advantages of the invention may be apparent from the following, more particular description of exemplary embodiments of the present invention, as illustrated in the accompanying drawings wherein like reference numbers generally indicate identical, functionally similar, and/or structurally similar elements:

FIG. 1 depicts a block diagram illustrating an input buffer circuit according to an embodiment of the present invention.

FIG. 2 depicts a detailed circuit diagram illustrating an exemplary first buffer as shown in FIG. 1.

FIG. 3 depicts a detailed circuit diagram illustrating an exemplary second buffer as shown in FIG. 1.

FIG. 4 depicts a detailed circuit diagram illustrating an exemplary output unit as shown in FIG. 1.

FIG. 5 depicts a timing chart illustrating the operation of the input buffer circuit according to the embodiment of the present invention.

### DETAILED DESCRIPTION OF EXEMPLARY EMBODIMENT

The present invention is now described in more detail with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

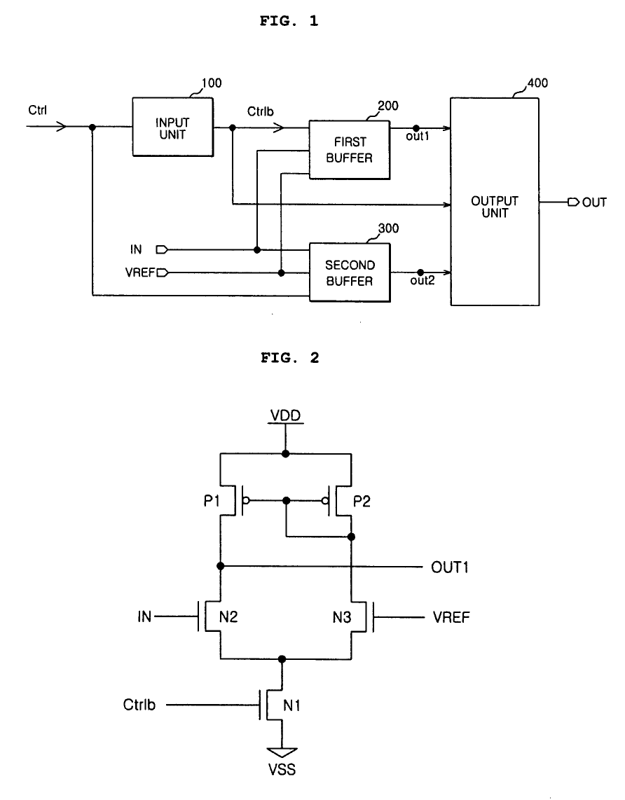

Referring to FIG. 1, an input buffer circuit according to an embodiment of the present invention includes an input unit 100, a first buffer 200, a second buffer 300, and an output unit 400.

The input unit 100 receives a control signal Ctrl and generates an inverted signal Ctrlb of the control signal Ctrl (hereinafter the inverted control signal). The control signal Ctrl is used to identify whether the device is in a self refresh mode or another mode such as the normal mode. The control signal Ctrl is activated in the self refresh mode. In an exemplary embodiment, the input unit 100 may be composed of an inverter.

The first buffer 200 operates to buffer an input signal when the inverted control signal Ctrlb is activated. That is, the first buffer 200 buffers an input signal in modes other than the self refresh mode, such as the normal mode. The processing speed of the first buffer 200 is higher than that of the second buffer 300. The first buffer 200 may be supplied with a reference voltage VREF having an intermediate level between a high level and a low level. When the inverted control signal Ctrlb is at a logic high level and an input signal IN has a higher level than the reference voltage VREF, the first buffer 200 outputs a logic high signal. When the inverted control signal Ctrlb is at a logic high level and the input signal IN has a lower level than the reference voltage VREF, the first buffer 200 outputs a logic low signal. In addition, when the inverted control signal Ctrlb is at a low level, the first buffer 200 is disabled and outputs a fixed high-level signal out1.

The first buffer 200 maybe composed of a differential buffer, according to an embodiment of the invention shown in FIG. 2. The first buffer 200 may include first to third NMOS transistors N1, N2, and N3 and first and second PMOS transistors P1 and P2. The first NMOS transistor N1 has a gate coupled to the inverted control signal Ctrlb and a source coupled to a ground signal. The second NMOS transistor N2 has a gate coupled to the input signal IN, a drain coupled to the drain of the PMOS transistor P1, and a source coupled to the drain of the first NMOS transistor N1. The third NMOS transistor N3 has a gate coupled to the reference voltage VREF, a drain coupled to the drain of the second PMOS transistor P2, and a source coupled to the source of the second NMOS transistor N2. The first PMOS transistor P1 has a gate coupled to the gate of the second PMOS transistor P2, a source coupled to an external voltage VDD, and a drain coupled to the drain of the second NMOS transistor N2. The second PMOS transistor P2 has a gate coupled to the gate of the first PMOS transistor P1, a source coupled to the external voltage VDD, and a drain coupled to the drain of the third NMOS transistor N3. The gate and the drain of the second PMOS transistor P2 are coupled to one another to form a current mirror.

When the control signal Ctrl is activated, the second buffer 300 operates to buffer the input signal IN, in self refresh mode. A static buffer having smaller current consumption than the first buffer 200 may be used as the second buffer 300.

As shown in FIG. 3, the second buffer 300 may include third and fourth PMOS transistors P3 and P4, and fourth and fifth NMOS transistors N4 and N5. The third PMOS transistor P3 has a gate coupled to the input signal IN, a source supplied with the external voltage VDD, and a drain coupled to the drain of the fourth NMOS transistor N4. The fourth PMOS transistor P4 includes a gate coupled to the control signal Ctrl, a source supplied with the external voltage VDD, and a drain coupled to the drain of the fourth NMOS transistor N4. The fourth PMOS transistor P4 is coupled in parallel to the third PMOS transistor P3. The fourth NMOS transistor N4 has a drain coupled to the input signal IN as well as the drains of the third and fourth transistors P3 and P4 and a source coupled to the fifth NMOS transistor N5. The fifth transistor N5 has a gate coupled to the control signal Ctrl, a drain coupled to the source of the fourth NMOS transistor N4, and a source coupled to the ground.

When the control signal Ctrl is at a logic high and the level of the input signal IN is higher than the reference voltage VREF, the second buffer 300 outputs a logic low signal. Meanwhile, when the level of the input signal IN is lower than the reference voltage VREF, the second buffer 300 outputs a logic high signal. When the control signal Ctrl is at a logic low, the second buffer 300 is disabled to output a fixed logic high signal out2.

In this embodiment, the first buffer 200 is driven by the inverted control signal Ctrlb, and the second buffer 300 is driven by the control signal Ctrl. In an alternative embodiment, the first buffer 200 may be driven by the control signal Ctrl, and the second buffer 300 may be driven by the inverted control signal Ctrlb.

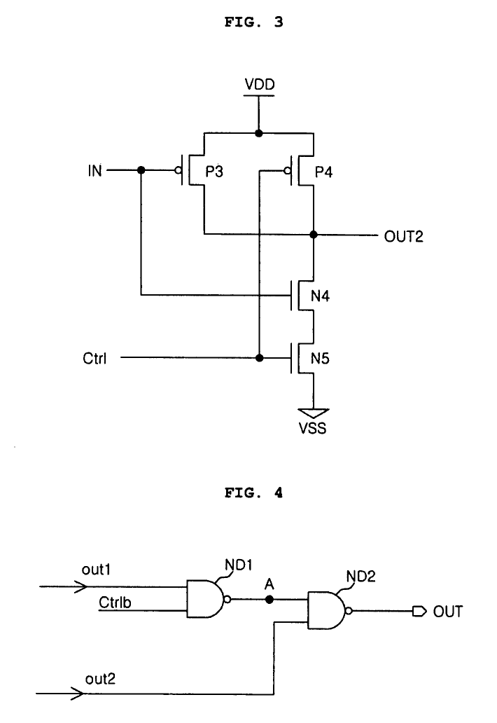

In an exemplary embodiment, the output unit 400 outputs the output signal out2 of the second buffer 300 when the control signal Ctrl is at a logic high, and outputs the output signal out1 of the first buffer 200 when the inverted control signal Ctrlb is at a logic high. As shown in FIG. 4, the output unit 400 may include a first NAND gate ND1 and a second NAND gate ND2. The output signal out1 of the first buffer 200 and the inverted control signal Ctrlb are input to the first NAND gate ND1, and the output signal out2 of the second buffer 300 and an output signal of the first NAND gate N1n are input to the second NAND gate ND2. The first NAND gate ND1 is used to invert the phase of the output signal out1 of the first buffer 200. When the inverted control signal Ctrlb is at a logic high level, the first NAND gate ND1 inverts the output of the first buffer 200 and outputs the inverted output to a node A. Meanwhile, when the inverted control signal Ctrlb is at a logic low level, the second buffer 300 is enabled and the second NAND gate ND2 outputs an inverted signal of the output of the second buffer 300.

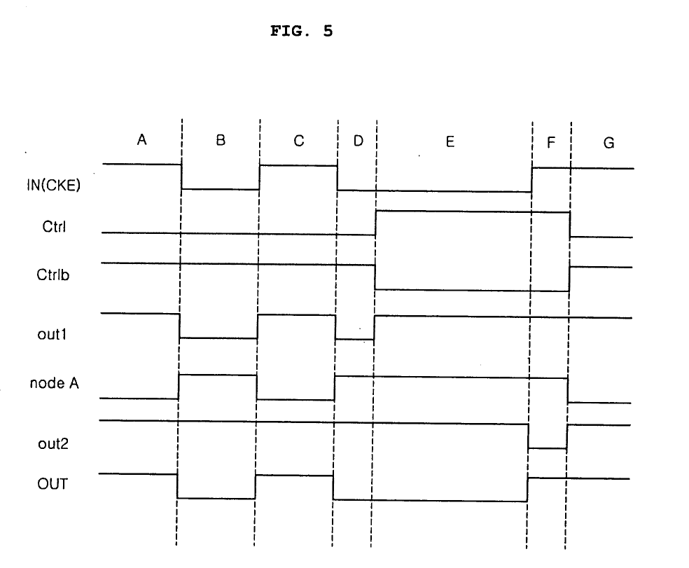

The operation of the input buffer circuit is now described with reference to FIG. 5.

Referring to FIG. 5, the control signal Ctrl is at a logic low level in modes other than the self refresh mode, e.g., the normal mode, and is at a high level in the self refresh mode.

The control signal Ctrl is at a logic low level in modes other than self refresh mode (depicted herein in periods A, B, C, and D). In addition, in modes other than self refresh mode, the first buffer 200 is enabled and the second buffer 300 is disabled. The output signal out1 of the first buffer 200 is a buffered signal of the input signal IN. Thus, when the input signal IN is a clock enable signal CKE, the first buffer 200 buffers the clock enable signal CKE (in the periods A, B, C, and D) . In the meantime, the output signal out2 of the second buffer 300 is fixed at a logic high level. Since the inverted control signal Ctrlb is at a logic high level in the other modes except for self refresh mode, the output of the first buffer 200 is inverted at the node A.

In self refresh mode (periods E and F), the control signal Ctrl is at a logic high level, the first buffer 200 is disabled, and the second buffer 300 is enabled. Therefore, the output signal out1 of the first buffer 200 is fixed at a logic high level, and the output signal out2 of the second buffer 300 is buffered with the phase thereof being opposite to that of the clock enable signal CKE (periods E and F). In this case, since the inverted control signal Ctrlb is at a logic low level, the level of the node A is fixed at a logic high level. Thus, an output signal OUT of the input buffer circuit is an inverted signal of the output signal out2 of the second buffer 300. As a result, the output signal OUT of the input buffer circuit has the same phase as the clock enable signal CKE and is buffered.

The first buffer 200, which is a differential buffer, is driven when a high-speed operation is required in modes other than the self refresh mode (e.g., the normal mode), and the second buffer 300, which is a static buffer having a small amount of current consumption, is driven in the self refresh mode requiring a small amount of current consumption.

The input buffer circuit according to the embodiments of the invention described herein uses different buffers depending on the operational modes, operating at a high speed using high current in modes other than the self refresh mode, while reducing the amount of current consumed in the self refresh mode.

It will be apparent to those skilled in the art that various modifications and changes may be made without departing from the scope and spirit of the present invention. Therefore, it should be understood that the above embodiments are not limitative, but illustrative in all aspects. The scope of the present invention is defined by the appended claims rather than by the description preceding them, and therefore all changes and modifications that fall within metes and bounds of the claims, or equivalents of such metes and bounds are therefore intended to be embraced by the claims.

What is claimed is:

1. An input buffer circuit comprising:
a first buffer configured to buffer an input signal when a control signal is activated; and
a second buffer configured to buffer the input signal when the control signal is activated,
wherein the first and second buffers selectively operate to output a signal in response to the control signal.

2. The input buffer circuit of claim 1, further comprising:
an input unit that generates an inverted control signal,
wherein the inverted control signal is input as the control signal to the first buffer.

3. The input buffer circuit of claim 1, further comprising:
an output unit that is connected to output terminals of the first and second buffers and selectively outputs signals output from the first and second buffers.

4. The input buffer circuit of claim 3,
wherein the output unit includes:
a first NAND gate having inputs adapted to receive the output of the first buffer and the inverted control signal to provide an output signal; and
a second NAND gate having inputs adapted to receive the output of the second buffer and the output signal of the first NAND gate.

5. The input buffer circuit of claim 1,
wherein the input signal includes a clock enable signal.

6. The input buffer circuit of claim 5,
wherein the control signal is activated in a self refresh mode.

7. The input buffer circuit of claim 5,
wherein the first and second buffers consume different amounts of current.

8. The input buffer circuit of claim 5,
wherein the first and second buffers include different operating speeds.

9. An input buffer circuit comprising:
a first buffer adapted to buffer a clock enable signal in modes other than a self refresh mode to provide an output signal;
a second buffer adapted to buffer the clock enable signal in the self refresh mode to provide an output signal; and
an output unit adapted to select output signals of the first and second buffers,
wherein the first buffer operates at a higher speed than the second buffer.

10. The input buffer circuit of claim 9,
wherein the output unit includes:
a first NAND gate having inputs adapted to receive the output signal of the first buffer and a signal for selecting the mode to provide an output signal; and
a second NAND gate having inputs adapted to receive the output signal of the second buffer and the output signal of the first NAND gate.

11. The input buffer circuit of claim 9,
wherein the first buffer comprises a differential buffer, and the second buffer comprises a static buffer.

12. An input buffer circuit comprising:
a first buffer configured to buffer a clock enable signal in a mode other than a self refresh mode to provide an output signal;
a second buffer configured to buffer the clock enable signal in the self refresh mode to provide an output signal; and
an output unit configured to select one of the output signal of the first buffer and the output signal of the second buffer,
wherein the first buffer is configured to operate at a higher speed than the second buffer, and
an amount of current consumed by the second buffer is smaller than an amount of current consumed by the first buffer.

13. The input buffer circuit of claim 12,
wherein the output unit includes:
a first NAND gate configured to receive the output signal of the first buffer and a signal for selecting the mode to provide an output signal; and
a second NAND gate configured to receive the output signal of the second buffer and the output signal of the first NAND gate.

14. The input buffer circuit of claim 12,
wherein the first buffer comprises a differential buffer, and the second buffer comprises a static buffer.
